(19) United States
(12) Patent Application Publication
(10) Pub. No.: US 2009/0128240 A1
(43) Pub. Date: May 21, 2009

(54) OSCILLATOR, PLL CIRCUIT, RECEIVER AND TRANSMITTER

(75) Inventor: Hiroshi Miyagi, Tokyo (JP)

Correspondence Address: PATENTTM.US, P. O. BOX 82788, PORTLAND, OR, 97282-0788, US

(73) Assignees: NIIGATA SEIMITSU CO., LTD., NIIGATA (JP); RICOH COMPANY LTD, TOKYO (JP)

(21) Appl. No.: 12/065,603

(22) PCT Filed: Jun. 27, 2006
(86) PCT No.: PCT/JP2006/312765

§ 371 Date: Mar. 3, 2008

(30) Foreign Application Priority Data
Sep. 13, 2005 (JP) 2005-264631

(51) Int. Cl. H03L 7/08

(52) U.S. Cl. 331/16

(57) ABSTRACT

An oscillator, a PLL circuit, a receiver and a transmitter that allow the circuit scale to be reduced and that are suitable for integration. The electrostatic capacities of variable capacitance circuits 230, 230A are made variable, thereby varying the oscillation frequency of a voltage controlled oscillator 21. The variable capacitance circuit 230 comprises a plurality of variable capacitance elements 60-64 the electrostatic capacities of which can be continuously varied by use of a control signal; a plurality of capacitors 50-54 which are associated with the respective variable capacitance elements and the electrostatic capacities of which are fixed; and a plurality of switches 71-74, 81-84 that individually switch combinational circuits, each of which comprises one of the plurality of variable capacitance elements 60-64 and a respective associated one of the plurality of capacitors 50-54, for selective connections.

### TECHNICAL FIELD

The present invention relates to an oscillator in which the oscillation frequency is set according to a control voltage, a PLL circuit, a receiver and a transmitter.

### BACKGROUND ART

To realize the reduced size and lower costs of a receiver, a technology for making a front-end module including a VCO (Voltage Controlled Oscillator) in chip form is well known (for example, see Japanese Patent Application Laid-Open No. 2003-110425). The oscillation frequency of the VCO is controlled by varying a voltage applied to a variable capacitance element included in the VCO, but because a capacity change of the variable capacitance element that can be implemented on the TC is small, a plurality of VCOs are provided to cover a wide variable range of frequencies in the receiver as disclosed in Japanese Patent Application Laid-Open No. 2003-110425 (pages 6 to 16, FIGS. 1 to 46).

### DISCLOSURE OF THE INVENTION

By the way, it was required that a plurality of VCOs having the same basic configuration are provided on the IC in the receiver as disclosed in Japanese Patent Application Laid-Open No. 2003-110425, whereby there was a problem that the apparatus scale was large.

This invention has been achieved in the light of the above-mentioned problem, and it is an object of the invention to provide an oscillator, a PLL circuit, a receiver and a transmitter that allow the circuit scale to be reduced and that are suitable for integration.

In order to solve the above problem, an oscillator according to the invention can make the electrostatic capacities of variable capacitance circuits variable, thereby varying the oscillation frequency. The variable capacitance circuit comprises a plurality of variable capacitance elements the electrostatic capacities of which can be continuously varied by use of a control signal, a plurality of capacitors which are associated with the respective variable capacitance elements and the electrostatic capacities of which are fixed, and a plurality of switches that individually switch combinational circuits, each of which comprises one of the plurality of variable capacitance elements and a respective associated one of the plurality of capacitors, for selective connections between the plurality of variable capacitance elements and the plurality of capacitors. Thereby, the electrostatic capacity of the variable capacitance circuit can be greatly changed, and the range of oscillation frequency can be set widely, by using one oscillator, whereby it is unnecessary to use the plurality of oscillators, allowing the circuit scale to be reduced. Also, the wide range of frequency can be changed by combining the variable capacitance element and the capacitor to be suitable for integration. Further, in the case where the plurality of oscillators are selectively used, it is required to send a current through the stand-by oscillators other than the selected oscillator which is operating at that time, in consideration of the stability of operation immediately after switching, whereby the power consumption is increased. On the contrary, one oscillator may be used, instead of the plurality of oscillators, whereby the lower power consumption is implemented.

Also, in the above combinational circuits, it is desirable that at least one set is always connected by bypassing a switch. Thereby, the number of switches can be reduced, and the switching on/off operation of the switch can be simplified. Also, it is possible to prevent a decrease in Q caused by an on-resistance of the switch or a distribution capacity, because the combinational circuit connected directly by bypassing the switch is provided.

Also, it is desirable that the coarse adjustment of the oscillation frequency is made by switching the interruption states of the plurality of switches, and the fine adjustment of the oscillation frequency is made by changing the electrostatic capacities of the variable capacitance elements by use of a control signal. Or it is desirable that any one of a plurality of oscillation frequency bands, which overlap one another, is selected by switching the interruption state of the plurality of switches, and the oscillation frequency is adjusted within the selected oscillation frequency band by changing the electrostatic capacities of the variable capacitance elements by use of a control signal. Thereby, the fine adjustment of the oscillation frequency can be made over the wide range by combining the coarse adjustment (switching the oscillation frequency bands) and the fine adjustment.

Also, it is desirable that the plurality of switches are provided individually for the variable capacitance elements and capacitors making up the combinational circuits, and the interruption states of the plurality of switches corresponding to one set of combinational circuits are switched at the same time. Or it is desirable that each of the plurality of switches is provided for each combinational circuit. In this way, the switch is provided for each variable capacitance element or each capacitor, or each combinational circuit made up of the variable capacitance elements and capacitors, whereby it is possible to securely switch the connected state of each combinational circuit.

Also, it is desirable that an inductor making up a resonation circuit together with the variable capacitance circuit and an amplification element connected to the resonation circuit are provided. In an oscillator having an LC resonation circuit, because the inductance of the inductor cannot be changed over the wide range, the electrostatic capacities of the variable capacitance circuits are instead changed over the wide range, whereby an LC oscillator with a wide range of oscillation frequency can be realized.

Also, it is desirable that all the components including the inductor are integrally formed on a semiconductor substrate using a CMOS process or a MOS process. Or it is desirable that all the components other than the inductor are integrally formed on a semiconductor substrate using a CMOS process or a MOS process. By producing the oscillator using these processes, the size and manufacturing costs of the oscillator can be reduced. In the case where all the components including the inductor are formed on the semiconductor substrate, the number of pads is reduced and the wiring is facilitated by eliminating an external component. On the other hand, in the case where the inductor is externally provided and the other components are formed on the semiconductor substrate, the low oscillation frequency and the high Q value can be easily realized.

A PLL circuit of the invention comprises the above mentioned oscillator within a phase locked loop. Specifically, the PLL circuit of the invention comprises the oscillator, a variable frequency divider for dividing an output signal of the oscillator at a frequency division ratio n settable from the outside, a phase comparator for making the phase comparison between an output signal of the variable frequency divider and a predetermined reference frequency signal, and a low pass filter for smoothing the output of the phase comparator to generate a control voltage as a control signal. The PLL circuit with the wide range of oscillation frequency can be easily realized by using the oscillator. In the oscillator, since the selected state is switched for each set of the variable capacitance element and the capacitor, there is uniform tendency of a change in the electrostatic capacities over the entire variable capacitance circuit to a variation amount ΔV of the control signal (control voltage) inputted into the variable capacitance elements, irrespective of the selected state. Accordingly, a lead-in time of the PLL circuit can be made almost constant without regard to the oscillation frequency.

Also, a receiver of the invention comprises a mixer for mixing an oscillation signal outputted from the PLL circuit and a reception signal received via an antenna, a filter for extracting a predetermined frequency component included in an output signal of the mixer, a demodulation circuit for performing a predetermined demodulating process for a signal after passing through the filter, and a control section for setting and changing the reception frequency by setting a frequency division ratio n of the variable frequency divider included in the PLL circuit. The receiver with the wide range of received frequency or band can be easily realized by using the PLL circuit having the oscillator. Also, the time required to switch the frequency can be prevented from varying with the frequency to be received by using the PLL circuit having almost constant lead-in time.

Also, a transmitter of the invention comprises a transmission circuit for transmitting a transmission signal from an antenna by generating the transmission signal with an oscillation signal outputted from the PLL circuit as a carrier, and a control section for setting and changing the transmission frequency by setting a frequency division ratio n of the variable frequency divider included in the PLL circuit. The transmitter with the wide range of transmission frequency or transmission band can be easily realized by using the PLL circuit having the oscillator. Also, the time required to switch the frequency can be prevented from varying with the transmission frequency to be switched by using the PLL circuit having almost constant lead-in time.

### BRIEF DESCRIPTION OF THE DRAWINGS

FIG. 1 is a diagram showing the basic configuration of a receiver according to one embodiment of the invention;

FIG. 2 is a diagram showing the detailed configuration of a voltage controlled oscillator;

FIG. 3 is a diagram showing an equivalent circuit of a switch;

FIG. 4 is a diagram showing another equivalent circuit of the switch;

FIG. 5 is a diagram showing the relationship between the oscillation frequency of the voltage controlled oscillator and the control voltage VT which is decided by a combination of the electrostatic capacities of a variable capacitance circuit and the inductance of an inductor;

FIG. 6 is a diagram showing the configuration of an unbalanced voltage controlled oscillator;

FIG. 7 is a diagram showing a modified configuration of the voltage controlled oscillator;

FIG. 8 is a diagram showing another modified configuration of the voltage controlled oscillator; and

FIG. 9 is a diagram showing the basic configuration of an FM transmitter as a transmitter according to another embodiment.

### DESCRIPTION OF SYMBOLS

10 input circuit
14 low noise amplifier (LNA)
16 mixer
20 local oscillator (LO)
21 voltage controlled oscillator (VCO)
26 intermediate frequency filter (IF filter)
28 intermediate frequency amplifier (IFA)
32 signal processing section
36 speaker
40 control section
42 operation section
44 display section
50 to 54 capacitors
60 to 64 variable capacitance elements
71 to 74, 81 to 84 switches
220 inductor
230, 230A variable capacitance circuits

### BEST MODE FOR CARRYING OUT THE INVENTION

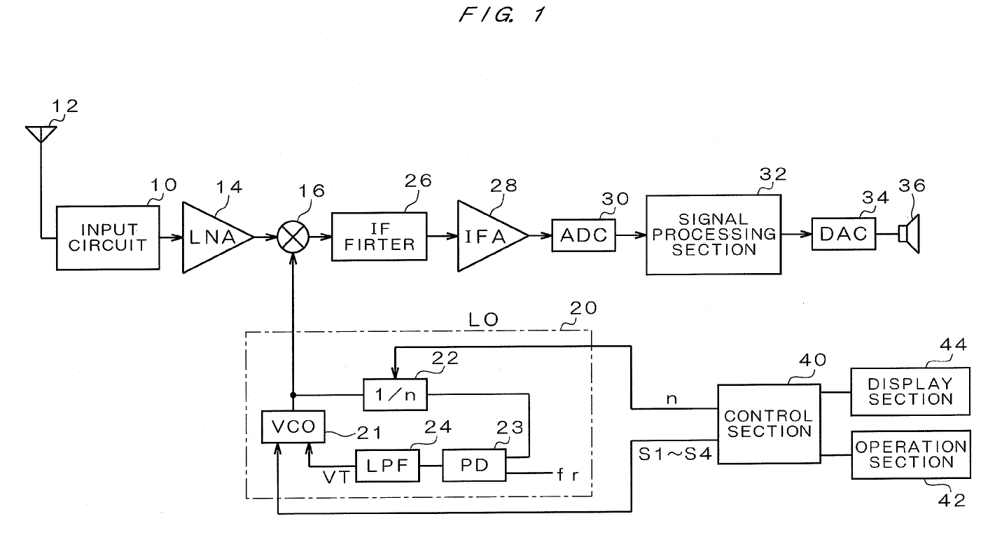

A receiver according to one embodiment of the present invention will be described below in detail. FIG. 1 is a diagram showing the basic configuration of the receiver according to one embodiment. The receiver of this embodiment comprises an input circuit 10, a low noise amplifier (LNA) 14, a mixer 16, a local oscillator (LO) 20, an intermediate frequency filter (IF filter) 26, an intermediate frequency amplifier (IFA) 28, an analog-digital converter (ADC) 30, a signal processing section 32, a digital-analog converter (DAC) 34, a speaker 36, a control section 40, an operation section 42, and a display section 44, as shown in FIG. 1. This receiver receives an FM broadcast wave, for an example, but has the same basic configuration when receiving an AM broadcast wave or television broadcast wave. Also, in this receiver, most of the components except for the antenna 12 and speaker 36 or a few other parts (e.g., a crystal oscillator required for generating the operation clock of the signal processing section 32 or an inductor included in the local oscillator 20) are integrally formed on a semiconductor substrate using a CMOS process or a MOS process.

The input circuit 10 comprises a tuning circuit for performing the impedance matching between the antenna 12 and the low noise amplifier 14 to select a broadcast wave desired to receive, or band pass filter, and the like. The low noise amplifier 14 amplifies a received signal inputted via the input circuit 10. The mixer 16 outputs a signal of mixing the received signal amplified by the low noise amplifier 14 and a local oscillation signal outputted from the local oscillator 20. The local oscillator 20 has the configuration of a PLL circuit, and generates and outputs a local oscillation signal having a frequency shifted by an intermediate frequency from a frequency of the broadcast wave desired to receive. For example, it outputs the local oscillation signal in the frequency range from about 60 MHz to 115 MHz.

The intermediate frequency filter 26 extracts and outputs an intermediate frequency component (intermediate frequency signal) from an output signal of the mixer 16. The intermediate frequency amplifier 28 amplifies the intermediate frequency signal extracted through the intermediate frequency filter 26. The analog-digital converter 30 samples the amplified intermediate frequency signal outputted from the intermediate frequency amplifier 28 at a predetermined frequency and converts it into digital data.

The signal processing section 32 performs various signal processings, including FM detection and a demodulating processing such as stereo demodulation, for the intermediate frequency signal converted into digital data to generate audio data. The digital-analog converter 34 converts the audio data outputted from the signal processing section 32 into an analog audio signal for output from the speaker 36. The control section 40 controls the overall operation of the receiver. Specifically, the control section 40 switches the oscillation frequencies of the local oscillator 20 according to a channel selection operation by the user with using the operation section 42, and displays a receiving state (received frequency (or broadcasting station name), wave strength, output volume, etc.) at that time on the display section 44.

Also, the local oscillator 20 of this embodiment comprises a voltage controlled oscillator (VCO) 21, a variable frequency divider 22 with a frequency division ratio n, a phase comparator (PD) 23, and a low pass filter (LPF) 24, as shown in FIG. 1. An output signal of the voltage controlled oscillator 21 is inputted into the mixer 16 as a local oscillation signal outputted from the local oscillator 20, and inputted into the variable frequency divider 22. The frequency division ratio n of the variable frequency divider 22 can be changed by the controller 40. The variable frequency divider 22 divides the output signal of the voltage controlled oscillator 21 at the frequency division ratio n, and inputs this frequency divided signal into one input terminal of the phase comparator 23. The phase comparator 23 makes the phase comparison between a signal inputted into this one input terminal and a reference frequency signal fr inputted into the other input terminal, and outputs a signal corresponding to a phase difference. The low pass filter 24 smoothes the output signal of the phase comparator 23 to generate a control voltage VT that is applied to the voltage controlled oscillator 21. The oscillation frequency of the voltage controlled oscillator 21 is set corresponding to the applied control voltage.

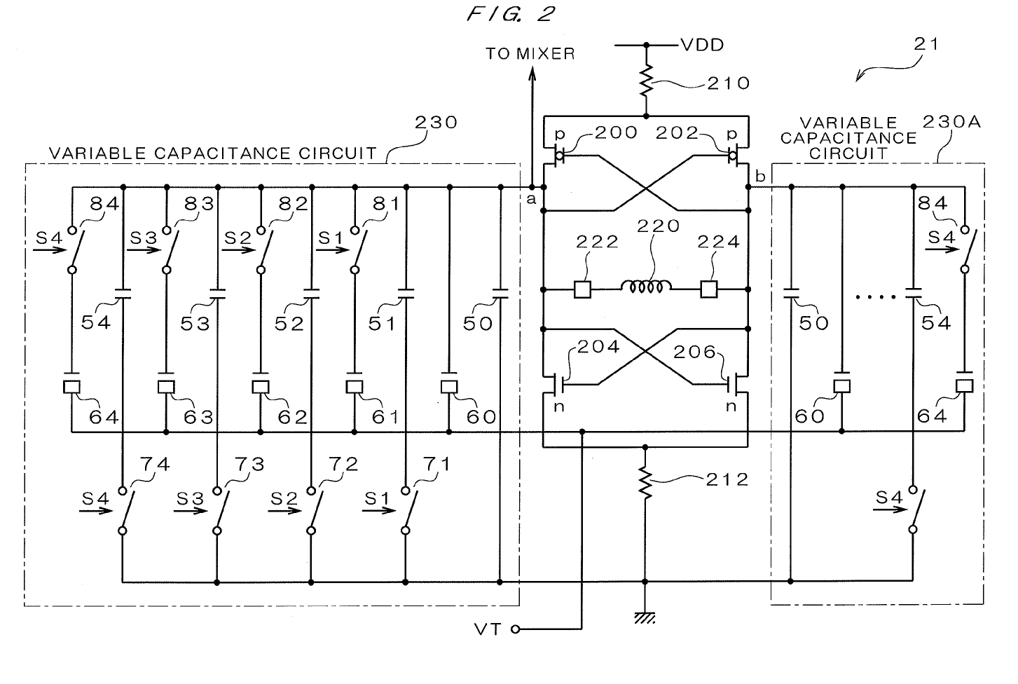

FIG. 2 is a diagram showing the detailed configuration of the voltage controlled oscillator 21. The voltage controlled oscillator 21 comprises two p-channel MOSFETs (pMOSFET) 200 and 202, two n-channel MOSFETs (nMOSFET) 204 and 206, two resistors 210 and 212, an inductor 220, and two variable capacitance circuits 230 and 230A having the same configuration, as shown in FIG. 2. The two pMOSFETs 200 and 202 have the drain connected commonly, with this connection point being connected via a resistor 210 to a power supply line (VDD) at the positive polarity side. The two nMOSFETs 204 and 206 have the source connected commonly, with this connection point being grounded via a resistor 212. Also, the source of the pMOSFET 200 and the drain of the nMOSFET 204 are connected (this connection point is supposed as a), with the gate of the other pMOSFET 202 and the gate of the other nMOSFET 206 being connected to this connection point a. Similarly, the source of the other pMOSFET 202 and the drain of the other nMOSFET 206 are connected (this connection point is supposed as b), with the gate of the pMOSFET 200 and the gate of the nMOSFET 204 being connected to this connection point b.

Also, one end of the inductor 220 and one end of the variable capacitance circuit 230 are connected to the connection point a. Also, the other end of the inductor 220 and the one end of the variable capacitance circuit 230A are connected to the connection point b. Both the variable capacitance circuits 230 and 230A are grounded at the other end.

An LC resonation circuit is made up of the inductor 220 and the two variable capacitance circuits 230 and 230A. The voltage controlled oscillator 21 oscillates at a resonance frequency which is decided including various parasitic components such as a parasitic capacitance. The inductor 220 may be realized by forming a wiring pattern spirally on the semiconductor substrate, or realized as an external component connected via two pads 222 and 224, as shown in FIG. 2.

The variable capacitance circuit 230 comprises five capacitors 50 to 54, five variable capacitance elements 60 to 64, and eight switches 71 to 74 and 81 to 84. One end of each of the five capacitors 50 to 54 is connected commonly to the connection point a. The other end of a capacitor 50 is grounded. The other end of a capacitor 51 is grounded via a switch 71. Similarly, the other end of a capacitor 52 is grounded via a switch 72. The other end of a capacitor 53 is grounded via a switch 73. The other end of a capacitor 54 is grounded via a switch 74. At one end of the five variable capacitance elements 60 to 64, a control voltage VT as a control signal for variably setting each capacitance value is applied commonly. The other end of a variable capacitance element 60 is connected to the connection point a. The other end of a variable capacitance element 61 is connected via a switch 81 to the connection point a. Similarly, the other end of a variable capacitance element 62 is connected via a switch 82 to the connection point a. The other end of a variable capacitance element 63 is connected via a switch 83 to the connection point a. The other end of a variable capacitance element 64 is connected via a switch 84 to the connection point a. Each of the variable capacitance elements 60 to 64 may be various kinds of element formable on the semiconductor substrate. For example, a variable capacitance diode the electrostatic capacity of which is varied according to an inverse bias voltage, or a MOS varactor the gate capacity of which is varied according to a gate voltage may be employed.

The switches 71 and 81 are turned on or off (controlled intermittently) by a switching signal S1 inputted from the control section 40. Similarly, the switches 72 and 82 are turned on or off by a switching signal S2 inputted from the control section 40. The switches 73 and 83 are turned on or off by a switching signal S3 inputted from the control section 40. The switches 74 and 84 are turned on or off by a switching signal S4 inputted from the control section 40. A variable capacitance circuit 230A has the same configuration as the variable capacitance circuit 230, and the detailed explanation thereof is omitted.

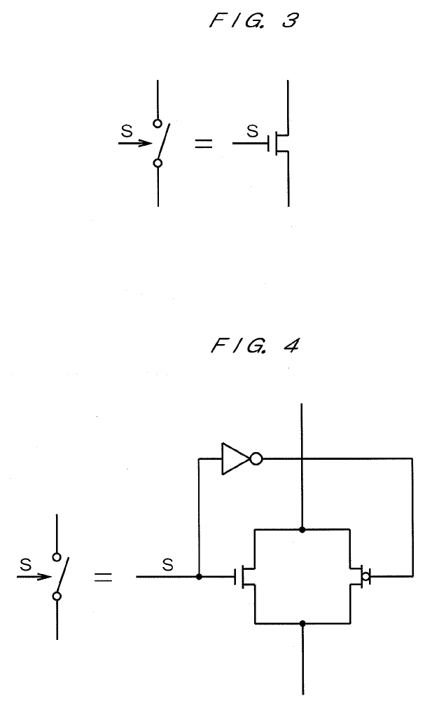

FIG. 3 is showing an equivalent circuit of the switches 71 to 74 and 81 to 84. The switches 71, and the like are implemented by inputting a control signal S1, or the like outputted from the control section 40 into the gate to turn on or off the source-drain, with using nMOSFET, as shown in FIG. 3.

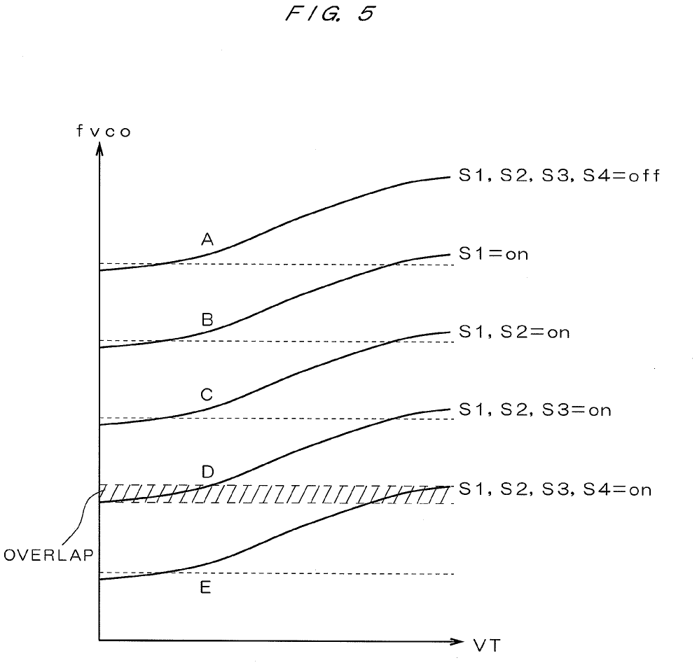

FIG. 4 is showing another equivalent circuit of the switches 71 to 74 and 81 to 84. The switches 71, and the like, are implemented by connecting the pMOSFET and the nMOSFET in parallel between source and drain, in which a control signal S1, and the like outputted from the control section 40 is directly inputted into the gate of the pMOSFET, and a signal in which the control signal S1, or the like is inverted by an inverter circuit is directly inputted into the gate of the nMOSFET, as shown in FIG. 4. With this configuration, there is less influence of source potential or drain potential upon the on-resistance between source and drain.

FIG. 5 is a diagram showing the relationship between the oscillation frequency of the voltage controlled oscillator 21 and the control voltage VT which is decided by a combination of electrostatic capacities of the variable capacitance circuits 230, 230A and inductance of the inductor 220. In FIG. 5, the ordinate corresponds to the oscillation frequency f_{VCO} of the voltage controlled oscillator 21 and the abscissa corresponds to the control voltage VT.

If all the switches 71 to 74 and 81 to 84 included in the variable capacitance circuit 230 are turned off, only a combinational circuit composed of the capacitor 50 and the variable capacitance element 60 within the variable capacitance circuit 230 is connected to the connection point a. In this connected state, the electrostatic capacity of the variable capacitance circuit 230 becomes the minimum. As it is same to the variable capacitance circuit 230A, in the following explanation the variable capacitance circuit 230 is only noted. Supposing that the electrostatic capacity of the variable capacitance circuit 230 is C and the inductance of the inductor 220 is L, the oscillation frequency f_{VCO} of the voltage controlled oscillator 21 has a value proportional to 1/√ (LC). Accordingly, if all the switches 71 to 74 and 81 to 84 included in the variable capacitance circuit 230 are turned off, the oscillation frequency f_{VCO} of the voltage controlled oscillator 21 is highest as indicated by characteristic line A in FIG. 5.

Next, if only the switches 71 and 81 included in the variable capacitance circuit 230 are turned off (other switches 72 to 74 and 82 to 84 are kept off), a combinational circuit composed of the capacitor 51 and the variable capacitance element 61, in addition to the combinational circuit composed of the capacitor 50 and the variable capacitance element 60, is connected to the connection point a. In this case, the oscillation frequency f_{VCO} of the voltage controlled oscillator 21 as indicated by characteristic line B in FIG. 5 is lower than the characteristic line A.

Similarly, a combinational circuit composed of the capacitor 52 and the variable capacitance element 62, a combinational circuit composed of the capacitor 53 and the variable capacitance element 63, and a combinational circuit composed of the capacitor 54 and the variable capacitance element 64 are added successively, whereby the oscillation frequency f_{VCO} of the voltage controlled oscillator 21 can be gradually lowered as indicated by characteristic lines C, D and E in FIG. 5.

For the five characteristics A to E as shown in FIG. 5 in this embodiment, the characteristic values (electrostatic capacity values) of each capacitor and each variable capacitance element are set so that the oscillation frequencies of adjacent characteristics may overlap one another. The extent of overlap may be set so that the continuous oscillation frequency can be made even if the characteristic value is dispersed at maximum, in consideration of dispersion in the characteristic value in the case where these elements are formed on the semiconductor substrate using the CMOS process or MOS process. It is desirable that the five characteristics A to E are set to have an almost equal interval AF.

As described above, each of the combinational circuits which comprises one of the plurality of variable capacitance elements and a respective associated one of the plurality of capacitors is regarded as a unit to switch the connections between the plurality of variable capacitance elements 60 to 64 and the plurality of capacitors 50 to 54. The electrostatic capacities of the variable capacitance circuits 230 and 230A can be greatly changed by individually switching the combinational circuit as a unit. Thereby, since the range of oscillation frequency can be set widely using one oscillator (voltage controlled oscillator 21), it is possible to reduce the circuit scale without need of using a plurality of oscillators. Also, the wide range of frequency can be changed by combining the variable capacitance elements and the capacitors to be suitable for integration. Further, in the case where a plurality of oscillators are selectively used, it is required to flow a current through other oscillators than the selected oscillator at that time, in consideration of the stability of operation immediately after switching, whereby the power consumption is increased. On the contrary, one oscillator can be used, instead of the plurality of oscillators, whereby the lower power consumption is realized.

Since at least one set of the combinational circuits (combinational circuit composed of the variable capacitance element 60 and the capacitor 50) is always connected by bypassing the switch, the number of switches 71 and the like can be reduced and the on/off switching operation of the switches can be simplified. Also, by comprising the combinational circuit directly connected by bypassing the switch 71 or the like, it is possible to prevent a decrease in Q caused by the on resistance of the switches or the distribution capacitance.

Also, in the voltage controlled oscillator 21 of this embodiment, the coarse adjustment of the oscillation frequency is made by switching the intermittent states of the plurality of switches 71 to 74 and 81 to 84, and the fine adjustment of the oscillation frequency is made by changing the electrostatic capacities of the variable capacitance elements 60 to 64 by use of a control signal. That is, any one of a plurality of oscillation frequency bands, which overlap one another, is selected by switching the intermittent states of the plurality of switches 71 to 74 and 81 to 84, and the oscillation frequency is adjusted within the selected oscillation frequency band by changing the electrostatic capacities of the variable capacitance elements 60 to 64 by use of the control signal. Thereby, the fine adjustment can be made for the wide range of oscillation frequency by combining the coarse adjustment (switching the oscillation frequency bands) and the fine adjustment.

Also, the plurality of switches 71 to 74 and 81 to 84 are provided individually for the variable capacitance elements 61 to 64 and the capacitors 51 to 54 making up the combinational circuits, and the intermittent states of two switches corresponding to one set of the combinational circuits are switched at the same time. Thereby, the connected state of each combinational circuit as a unit can be securely switched.

Also, in the voltage controlled oscillator 21 having the LC resonation circuit, because the inductance of the inductor cannot be changed over the wide range, the electrostatic capacities of the variable capacitance circuits 230 and 230A are instead changed, whereby the LC oscillator with the wide range of oscillation frequency can be realized.

Also, all the components of the voltage controlled oscillator 21 and the local oscillator 20 other than the inductor 220 may be integrally formed on the semiconductor substrate using the CMOS process or MOS process, whereby the size and manufacturing costs of the voltage controlled oscillator 21 and the local oscillator 20 can be reduced. In the case where the inductor 220 is externally provided and the other components are formed on the semiconductor substrate, the low oscillation frequency and the high Q value can be easily realized.

In the receiver of this embodiment, the local oscillator 20 as the PLL circuit with the wide range of oscillation frequency can be easily realized by using the voltage controlled oscillator 21. Particularly for the voltage controlled oscillator 21, because the selected state is switched for each set of the variable capacitance element and the capacitor as a unit, there is uniform tendency of a change in the electrostatic capacities over the entire variable capacitance circuit with respect to a variation amount ΔV of the control signal (control voltage) inputted into the variable capacitance element, irrespective of the selected state. Accordingly, a lead-in time of the PLL circuit can be made almost constant without regard to the oscillation frequency.

Also, in the receiver of this embodiment, since the voltage controlled oscillator 21 and the local oscillator 20 as the PLL circuit are used, the receiver in which the range of received frequency or the reception band is wide can be easily realized. Also, it is possible to prevent the time required to switch the frequency from varying with the frequency to be received by using the PLL circuit in which the lead-in time is almost constant.

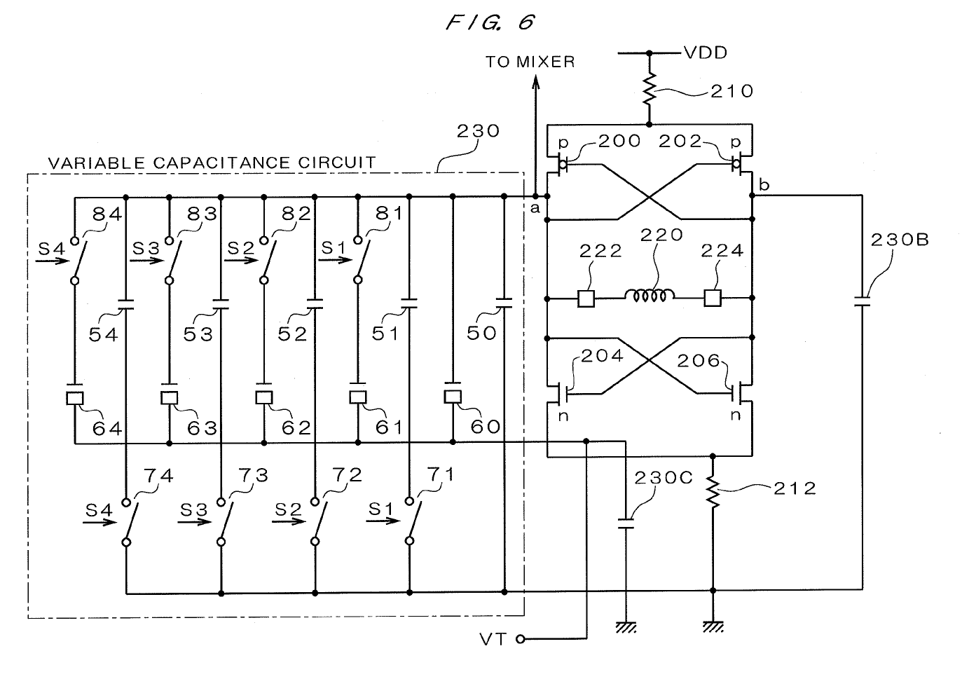

The invention is not limited to the above embodiment, but various modifications may be made within the scope of the invention as claimed. Though the voltage controlled oscillator 21 as shown in FIG. 2 has a balanced configuration in which the variable capacitance circuits 230 and 230A having the same electrostatic capacities are connected to both the connection points a and b, it may adopt an unbalanced configuration in which the variable capacitance circuit 230A connected to the connection point b is replaced with a fixed capacitor 230B having a fully greater electrostatic capacity than the variable capacitance circuit 230, as shown in FIG. 6. In this case, it is required to add a capacitor 230C having one end connected to a feeding point of the control voltage VT, with the other end grounded. This capacitor 230C has a fully greater electrostatic capacity than the variable capacitance circuit 230.

Though the variable capacitance circuit 230 is used for the voltage controlled oscillator 21 having the configuration shown in FIG. 2 in the above embodiment, the invention may be applied by including the variable capacitance circuit 230 in the LC oscillator or CR oscillator having the other configuration.

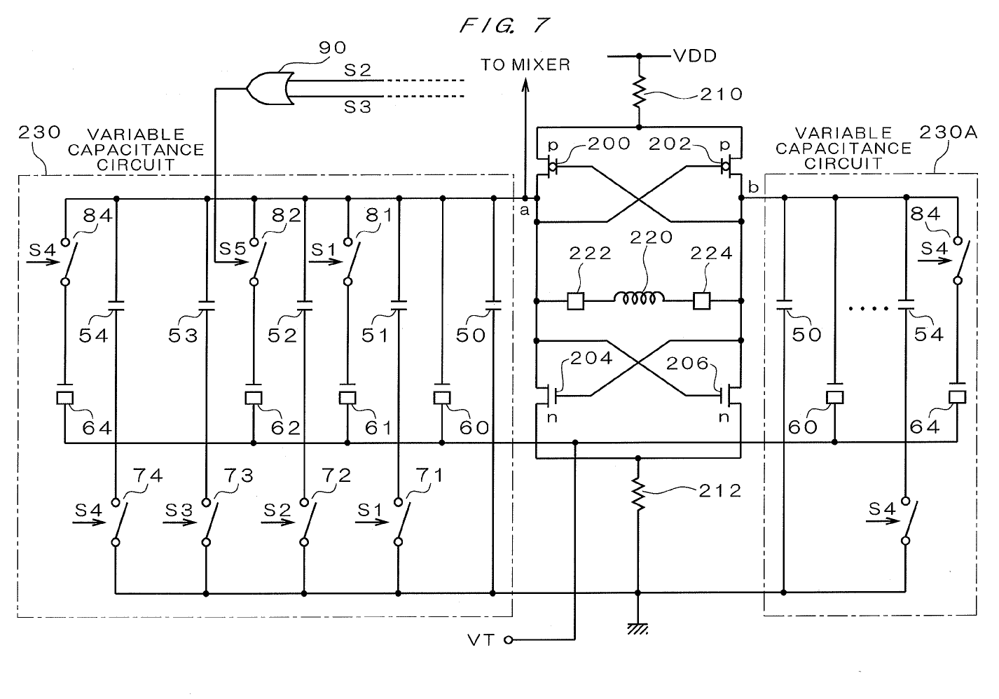

Also, though the combinational circuits are composed of the capacitors and the variable capacitance elements associated one-to-one in the variable capacitance circuit 230 within the voltage controlled oscillator 21 as shown in FIG. 2, part of the variable capacitance elements may be omitted, or two or more capacitors may share one variable capacitance element. For an example, the variable capacitance element 63 and the switch 83 are omitted (from the configuration shown in FIG. 2), and one variable capacitance element 62 may be associated with two capacitors 52 and 53, as shown in FIG. 7. In this case, the switch 72 is controlled for on/off by use of a control signal S2, and the switch 73 is controlled for on/off by use of a control signal S3, in the same manner as shown in FIG. 2, but the switch 82 to which the variable capacitance element 62 to be associated in common is connected may be controlled for on/off by generating a logical sum signal S5 of two control signals S2 and S3 by an OR circuit 90.

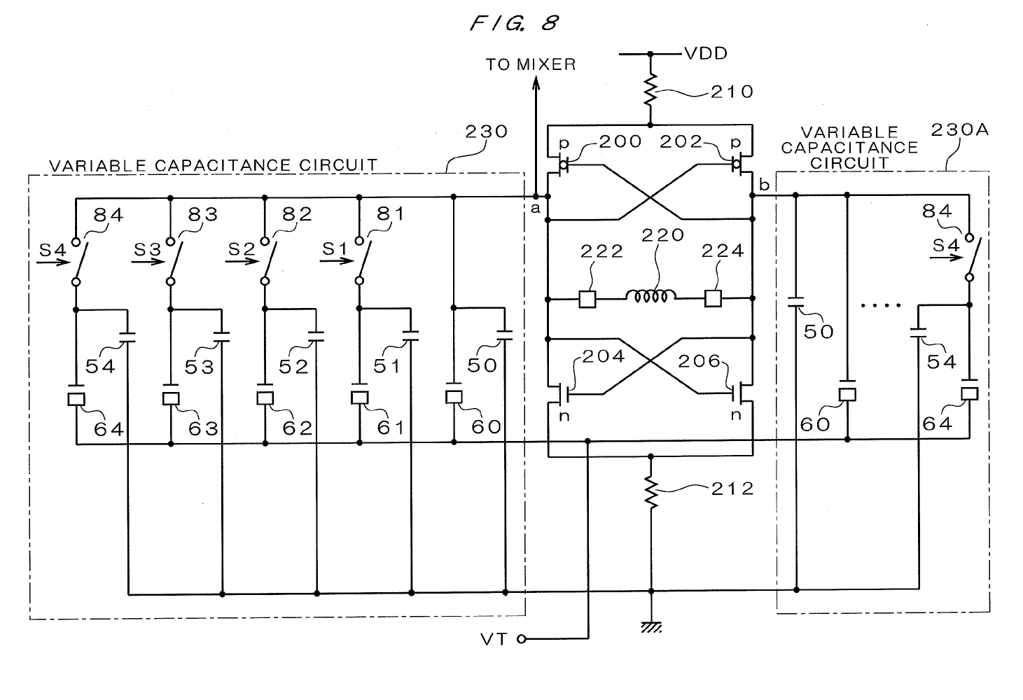

Also, though the switches are separately connected to both the variable capacitance element and the capacitor making up the set of combinational circuit in the above embodiment, these switches may be integrated into one switch. For an example, the switches 71 to 74 may be eliminated and the switches 81 to 84 may be shared, as shown in FIG. 8.

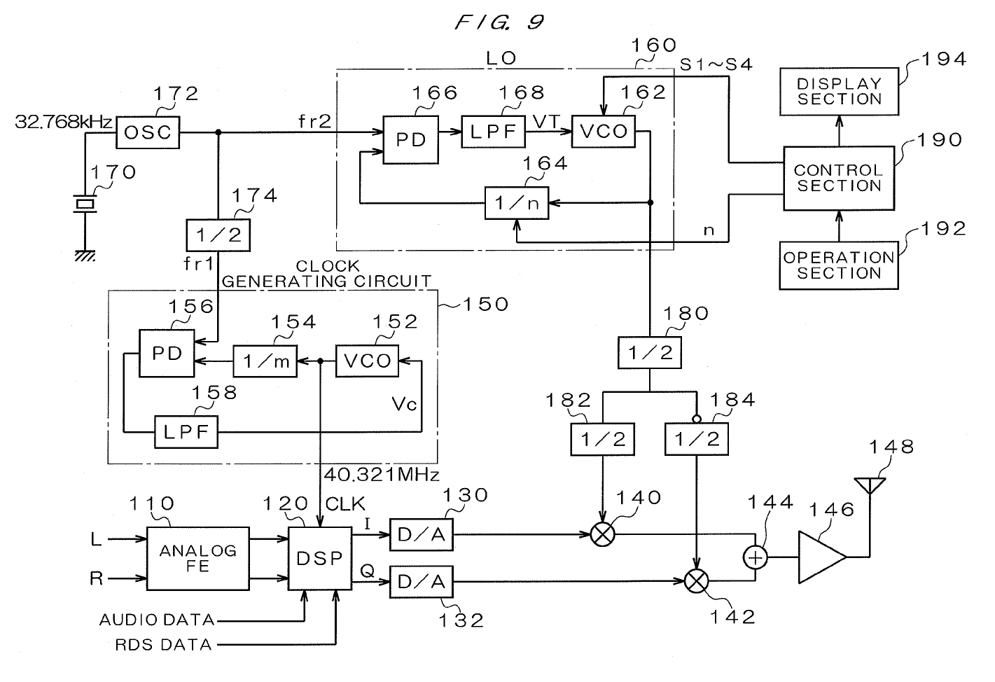

Also, though the receiver has been described in the above embodiment, the oscillator of the invention may be employed for a transmitter. FIG. 9 is a diagram showing the basic configuration of an FM transmitter as a transmitter according to another embodiment. The FM transmitter as shown in FIG. 9 comprises an analog front end (analog FE) 110, a DSP (digital signal processor) 120, the digital-analog (D/A) converters 130 and 132, the mixers 140 and 142, an adder 144, an amplifier 146, an antenna 148, a clock generating circuit 150, a local oscillator (LO) 160, a crystal resonator 170, an oscillator (OSC) 172, the frequency dividers 174, 180, 182 and 184, a control section 190, an operation section 192 and a display section 194.

The analog front end 110 has an analog stereo signal composed of an L signal and an R signal inputted, and converts it into L data and R data as digital stereo data. The DSP 120 performs digitally a stereo modulation process, an FM modulation process and an IQ modulation process, based on L data and R data outputted from the analog front end 110. Also, the DSP 120 has audio data or RDS data inputted, and performs various kinds of processes as described above for these data. The DSP 120 outputs I data and Q data that were subjected to the IQ modulation process.

A digital-analog converter 130 converts I data outputted from the DSP 120 into an analog I signal. Also, a digital-analog converter 132 converts Q data outputted from the DSP 120 into an analog Q signal. A mixer 140 mixes the I signal outputted from the digital-analog converter 130 with a predetermined local oscillation signal (hereinafter called a first local oscillation signal) to output. A mixer 142 mixes the Q signal outputted from the other digital-analog converter 132 with a local oscillation signal (hereinafter called a second local oscillation signal) which is 90° out of phase with the first local oscillation signal to output. The adder 144 adds the signals outputted from two mixers 140 and 142 to output. The output of the adder 144 is power amplified by the amplifier 146, and then transmitted from the antenna 148. The mixers 140 and 142, the adder 144 and the amplifier 146 correspond to a send circuit.

The clock generating circuit 150 generates an operation clock signal CLK required for the digital processing of the DSP 120. A reference frequency signal fr1 of 16.384 kHz, for an example, is inputted into the clock generating circuit 150, and a clock signal CLK with a frequency (40.321 MHz) of 2461 times the reference frequency is generated synchronously with this reference frequency signal. For the purpose of the above, the clock generating circuit 150 comprises a voltage controlled oscillator (VCO) 152, a variable frequency divider (1/m) 154, a phase comparator (PD) 156, and a low pass filter (LPF) 158. The voltage controlled oscillator 152 performs the oscillation operation of frequency corresponding to a control voltage Vc. The variable frequency divider 154 divides an output signal of the voltage controlled oscillator 152 at a fixed frequency division ratio m (=2461) to output. The phase comparator 156 makes the phase comparison between a frequency divided signal outputted from the frequency divider 154 and the reference frequency signal fr1, and outputs a pulse signal with a duty corresponding to a phase difference. The low pass filter 158 smoothes the pulse signal outputted from the phase comparator 156 to generate the control voltage Vc that is supplied to the voltage controlled oscillator 152. In this manner, the clock generating circuit 150 has the PLL configuration, and generates a clock signal CLK with a frequency (40.321 MHz) of 2461 times the frequency of the reference frequency signal fr1 and inputs it into the DSP 120.

The local oscillator 160 generates an oscillation signal required to generate the first and second local oscillation signals inputted into the mixers 140 and 142. A reference frequency signal fr2 of 32.768 kHz, for an example, is inputted into the local oscillator 160, and a signal with a frequency of n times this reference frequency is generated synchronously with this reference frequency signal. For the purpose of the above, the local oscillator 160 comprises a voltage controlled oscillator (VCO) 162, a variable frequency divider (1/n) 164, a phase comparator (PD) 166, and a low pass filter (LPF) 168. The voltage controlled oscillator 162 performs the oscillation operation of frequency corresponding to the control voltage VT. The variable frequency divider 164 divides an output signal of the voltage controlled oscillator 162 at a variable frequency division ratio n. The phase comparator 166 makes the phase comparison between a frequency divided signal outputted from the variable frequency divider 164 and the reference frequency signal fr2, and outputs a pulse signal with a duty corresponding to a phase difference. The low pass filter 168 smoothes the pulse signal outputted from the phase comparator 166 to generate the control voltage VT that is supplied to the voltage controlled oscillator 162. In this manner, the local oscillator 160 is a PLL circuit having the PLL configuration, and generates a signal having a frequency of n times the frequency of the reference frequency signal fr2. The frequency division ratio n of the variable frequency divider 164 is set by the control section 190.

The oscillator 172 is connected to a crystal resonator 170 and oscillates at a natural oscillation frequency of this crystal resonator 170. The crystal resonator 170 having a natural oscillation frequency of 32.768 kHz, which is easily available at a low price, is employed in this embodiment. An oscillation signal of 32.768 kHz outputted from the oscillator 172 is inputted as the reference frequency signal fr2 into the local oscillator 160, and a signal of 16.384 kHz after passing through the frequency divider 174 having a frequency division ratio of 2 is inputted as the reference frequency signal fr1 into the clock generating circuit 150.

Each of three frequency dividers 180, 182 and 184 has a frequency division ratio set to 2, and generates a signal having one-quarter the frequency of the output signal of the voltage controlled oscillator 162 within the local oscillator 160 as a first local oscillation signal, and a signal having the same frequency as this first local oscillation signal and only the phase different by 90° as a second local oscillation signal.

The control section 190 controls the FM transmitter as a whole. For examples, the control section 190 sets the frequency division ratio of the variable frequency divider 164 within the local oscillator 160 and decides the transmission frequency of an FM signal. The operation section 192 has various kinds of switches operated by the user. For examples, a power supply switch, an up key and a down key for directing the switching between the transmission frequencies, and a selection key (directing which of analog audio signal and digital audio data to transmit) for selecting the resource to be transmitted. The display section 194 displays the transmission frequency, the operation contents of the operation section 192 and the battery remaining amount.

For the FM transmitter having the above configuration, all the components except for the crystal resonator 170, the antenna 148, the operation section 192 and the display section 194 are integrally formed on the semiconductor substrate using the CMOS process or MOS process. Also, the voltage controlled oscillator 162 within the local oscillator 160 may have any one of the configurations as shown in FIG. 2, 6, 7 or 8, whereby the range of transmission frequency or transmission band can be easily wider, as is the case with the receiver. Also, in switching the transmission frequencies, the time required to switch the frequency is prevented from varying with the transmission frequency to be switched.

### INDUSTRIAL APPLICABILITY

With the invention, since the electrostatic capacities of the variable capacitance circuit can be greatly changed, and the range of oscillation frequency can be set widely using one oscillator, there is no need of using a plurality of oscillators, and thereby it is possible to reduce the circuit scale. Also, the wide range of frequency can be changed by combining the variable capacitance elements and the capacitors to be suitable for integration. Further, in the case where the plurality of oscillators are selectively used, it is required to flow a current through other oscillators than the oscillator which is working at that time, in consideration of the stability of operation immediately after switching, whereby the power consumption is increased. On the contrary with this invention, one oscillator can be used, instead of the plurality of oscillators, whereby the lower power consumption is realized.

1. An oscillator that can change oscillation frequency by varying electrostatic capacity of a variable capacitance circuit, the variable capacitance circuit comprising:
a plurality of variable capacitance elements the electrostatic capacities of which can be continuously varied by use of a control signal;
a plurality of capacitors which are associated with the respective variable capacitance elements and electrostatic capacities of which are fixed; and
a plurality of switches that individually switch combinational circuits, each of which comprises one of the plurality of variable capacitance elements and a respective associated one of the plurality of capacitors for selective connections between the plurality of variable capacitance elements and the plurality of capacitors.

2. The oscillator according to claim 1, wherein at least one set of the combinational circuits is always connected by bypassing the switch.

3. The oscillator according to claim 1, wherein coarse adjustment of the oscillation frequency is made by switching intermittent states of the plurality of switches, and fine adjustment of the oscillation frequency is made by changing the electrostatic capacities of the variable capacitance elements by use of the control signal.

4. The oscillator according to claim 1, wherein any one of a plurality of oscillation frequency bands, which overlap one another, is selected by switching the intermittent states of the plurality of switches, and the oscillation frequency is adjusted within the selected oscillation frequency band by changing the electrostatic capacities of the variable capacitance elements by use of the control signal.

5. The oscillator according to claim 1, wherein the plurality of switches are provided individually for the variable capacitance elements and the capacitors making up the combinational circuits, and the intermittent states of the plurality of switches corresponding to one set of the combinational circuits are switched at the same time.

6. The oscillator according to claim 1, wherein each of the plurality of switches is provided for each of the combinational circuits, respectively.

7. The oscillator according to claim 1, wherein an inductor making up a resonation circuit together with the variable capacitance circuit and an amplification element connected to the resonation circuit are provided.

8. The oscillator according to claim 7, wherein all the components including the inductor are integrally formed on a semiconductor substrate using a CMOS process or a MOS process.

9. The oscillator according to claim 7, wherein all the components other than the inductor are integrally formed on a semiconductor substrate using a CMOS process or a MOS process.

10. A PLL circuit comprising an oscillator that can change oscillation frequency by varying electrostatic capacity of a variable capacitance circuit within a phase locked loop, the variable capacitance circuit comprising:
a plurality of variable capacitance elements the electrostatic capacities of which can be continuously varied by use of a control signal;
a plurality of capacitors which are associated with the respective variable capacitance elements and electrostatic capacities of which are fixed; and
a plurality of switches that individually switch combinational circuits, each of which comprises one of the plurality of variable capacitance elements and a respective associated one of the plurality of capacitors for selective connections between the plurality of variable capacitance elements and the plurality of capacitors.

11. The PLL circuit according to claim 10, further comprising:
the oscillator;
a variable frequency divider for dividing an output signal of the oscillator at a frequency division ratio n settable from outside;
a phase comparator for making phase comparison between an output signal of the variable frequency divider and a predetermined reference frequency signal; and
a low pass filter for smoothing output of the phase comparator to generate a control voltage as the control signal.

12. A receiver comprising:
the PLL circuit according to claim 11;
a mixer for mixing an oscillation signal outputted from the PLL circuit and a reception signal received via an antenna;
a filter for extracting a predetermined frequency component included in an output signal of the mixer;
a demodulation circuit for performing a predetermined demodulation process for a signal after passing through the filter; and
a control section for setting and changing the reception frequency by setting a frequency division ratio n of the variable frequency divider included in the PLL circuit.

13. A transmitter comprising:
the PLL circuit according to claim 11;
a transmission circuit for transmitting a transmission signal from an antenna by generating transmission signal with an oscillation signal outputted from the PLL circuit as a carrier; and
a control section for setting and changing transmission frequency by setting a frequency division ratio n of the variable frequency divider included in the PLL circuit.
